(19) United States
(12) Patent Application Publication
(10) Pub. No.: US 2007/0030718 A1
(43) Pub. Date: Feb. 8, 2007

(54) Magnetic logic system

(75) Inventor: Russell Paul Cowburn, London (GB)

Correspondence Address: MCDONNELL BOEHNEN HULBERT & BERGHOFF LLP, 300 S. WACKER DRIVE, 32ND FLOOR, CHICAGO, IL, 60606, US

(73) Assignee: Ingenia Technology Limited

(21) Appl. No.: 10/547,141

(22) PCT Filed: Feb. 27, 2004
(86) PCT No.: PCT/GB04/00840

§ 371 Date: Oct. 31, 2006

(30) Foreign Application Priority Data
Feb. 28, 2003 (GB) 0304610.9

(51) Int. Cl. G11C 11/06

(52) U.S. Cl. 365/55

(57) ABSTRACT

A driving system and method to effect propagation of a magnetic domain wall through a ferromagnetic conduit are described, wherein oscillating electrical current is passed through the conduit from an oscillating current supply source via at least two electrical contacts adapted to make electrical connection with at least two spaced points on the conduit. A ferromagnetic conduit is described comprising an elongate ferromagnetic element formed as a continuous track of magnetic material capable of sustaining and propagating a domain wall, and such a driving system in serial array, preferably being further adapted to serve as a magnetic logic element by the provision of nodes and/or directional changes as a result of which logical functions may be processed.

The invention relates to the provision of a driving system and method to effect propagation of a magnetic domain wall through a conduit in a magnetic logic system, and to a magnetic logic system and method of operation of such a system incorporating the same.

International Patent Application WO 02/41492 described a novel system for digital logic that used magnetic domain walls or solitons passing along lithographically defined magnetic conduits. Conduits were described either made from networks of magnetostatically interacting single domain particles, or from continuous sub-micron width tracks of ferromagnetic material.

In conventional microelectronic digital logic, the two Boolean states ‘1’ and ‘0’ are signalled by a high voltage and a low voltage. In the proposed nanomagnetic logic scheme in the above reference, the two Boolean states are signalled by the direction of magnetisation within the conduit. A conventional microelectronic system communicates a change of Boolean state from one point on the chip to another by transmitting a rising- or falling-edge of potential along a length of electrically conductive interconnect.

A property of electrically conducting materials is that such potential changes obey a wave equation and so the rising- or falling-edges do not need to be explicitly propelled. In the proposed nanomagnetic logic scheme in the above reference, in one embodiment, a change in Boolean state is communicated by transmitting a magnetic domain wall down the magnetic conduit. In contrast to the electrical case, however, the domain wall is not self-propelling due to pinning at edge defects and so must be explicitly moved by a force. In the disclosure referred to, it was proposed that the force should come from a magnetic field which rotates with time, which also acts as the synchronous clock for the system.

While the rotating field is very effective at propelling domain walls, it is inconvenient to have to generate such a field, because relatively high currents and bully coils are usually required. This is particularly a problem in portable applications such as lap-top computers and mobile phones, where the power required to generate the magnetic field would be a significant drain on the limited battery capacity.

There is thus a general desire to provide a driving system and method to effect propagation of the magnetic domain wall in such a logic system, and a magnetic logic system and method of operation of such a system incorporating the same, which does not require the high energy input externally generated magnetic driving field described in the reference. This is particularly the case if the logic system is to be applied to practical portable devices where power capacity is limited.

It is an object of the invention to provide a driving system and method to effect propagation of a magnetic domain wall through a ferromagnetic conduit in a magnetic logic system, and to provide a magnetic logic system and method of operation of such a system incorporating the same, which mitigates some of the disadvantages of prior art systems, and in particular which reduces the energy input require to effect translation of the domain wall along the conduit.

It is a particular object of the present invention to provide a driving system and method alternative to that described in the above reference, and especially a system and method which does not involve application of a varying magnetic field.

Thus, in accordance with the invention in a first aspect, a driving system to effect propagation of a magnetic domain wall through a ferromagnetic conduit, for example in a logic system such as that described in the above reference, comprises at least two electrical contacts adapted to make electrical connection with at least two spaced points on a ferromagnetic conduit, and an electrical current source to supply oscillating current thereto, and thus in use with the contacts in place to pass an oscillating electrical current through the conduit.

It is found that such an applied electrical current is effective in propelling magnetic domain walls down continuous tracks of ferromagnetic material and providing a synchronous clock without involving any externally applied magnetic field. Consequently, devices that incorporate this invention will be physically less bullry and use less energy than those that use an externally applied magnetic field.

Whilst the invention is not necessarily limited to any specific theory, it is considered that the applied electrical current is effective in propelling magnetic domain walls down continuous tracks of ferromagnetic material by because of the “spin transfer effect”.

Two very important scientific papers outlining this theory in principle were published in 1996 by Slonczewski (J. C. Slonczewski, J. Magn. Magn. Mater. 159, L1 (1996)) and Berger (L. Berger, Phys. Rev. B 54, 9353 (1996)). Using slightly different formalisms, each predicted that if an electrical current were passed between two ferromagnetic layers, then the conduction electrons should become spin polarised in one layer, causing them to exert a torque on the other layer. This torque was named spin-transfer torque, because it comes from the spin of the conduction electrons being transferred from one layer to another.

The first verification of this prediction was made in 1999 by Myers et al. (E. B. Myers, D. C. Ralph, J. A. Katine, R. N. Louie, R. A. Buhrman, Science 285, 867 (1999)), who succeeded in magnetically switching one of the two ferromagnetic layers comprising a magnetic spin-valve, simply by passing an electrical current between the two layers. Although a very high current density was required to achieve a noticeable spin transfer effect, the small cross sectional area of the devices (typically 100 nm×100 nm) meant that the actual current were very small, and certainly much smaller than that which would be needed to power external field coils to achieve the same switching through a classical magnetic field. It is important to stress that spin transfer is a new, non-classical effect and does not involve the generation of a magnetic field. A brief overview of spin transfer has been given by Ralph (D. Ralph, Science 291, 999 (2001)).

According to the present invention it is possible to exert a translational force on a magnetic domain wall by passing an electrical current through it, through the spin transfer effect, which can be used to propel domain walls along domain wall conduits in nanomagnetic logic devices. Conduction electrons will become spin polarised in the uniformly magnetised region to one side of the domain wall; as they pass through the wall itself, that spin polarisation causes the spins in the core of the wall to precess, and the wall to move in the direction of the electron flow (i.e. opposite to the direction of conventional current flow).

If the domain wall is inside a conduit of width less than 1 μm and thickness less than 50 nm, the current required to move the domain wall is very small (typically 1 mA or less). This is to be compared with typically 1A, which is the current required to generate enough classical magnetic field (using strip lines of field coils) to move the same wall by classical means, and so one sees that this invention leads to great efficiency and much reduced power requirements compared with the rotating magnetic field suggested in the prior art. Devices built based on the logic are much more efficient, and small, portable devices or other devices with inherently limited power supplies are much more practicable.

The electrical current source is adapted to supply oscillating current to the contacts, and thus in use with the contacts in place to pass an oscillating electrical current through the ferromagnetic conduit. It is an advantage of the invention that this current can be relatively low, preferably below 100 mA, more preferably below 10 mA. The frequency of oscillation is from KHz to hundreds of MHz, for example between 1 kHz and 1 GHz, and in particular between 20 kHz and 500 MHz. Any suitable oscillating waveform may be used, including without limitation sinusoidal, triangular or square wave or bit sequence.

In a further aspect, the invention comprises a ferromagnetic conduit for a magnetic logic system comprising an elongate ferromagnetic element formed as a continuous track of magnetic material capable of sustaining and propagating a domain wall, and in particular a generally elongate, planar, thin layer ferromagnetic structure, and a driving system comprising a serial array of electrical contacts as above described spaced along the length of the conduit or a part thereof. The conduit is thus for example one of the conduit structures described by International Patent Application WO 02/41492 the content of which is incorporated herein by reference.

The contacts in the serial array may be evenly spaced, for example to avoid discontinuities in resistance between different adjacent pairs. Alternatively the contacts may be irregularly spaced, or may have a particular non-uniform spacing pattern to produce a desired effect, for example to introduce, augment or modify a discontinuity in the conduit for example in association with suitable structural features in the conduit to effect a particular logical function or the like.

The at least two electrical contacts are adapted to make electrical connection with at least two spaced points along the ferromagnetic conduit and thus to pass an electrical current along the conduit and cause a domain wall to be moved longitudinally therebetween. The at least two electrical contacts are preferably disposed on the conduit so as to apply an electric current to flow generally in a longitudinal direction along the conduit. Most preferably, each driving contact comprises a contact member extending transversely across the track or a part thereof.

In a preferred embodiment, the driving system comprising a serial array of driving contacts as above described along the length of the conduit or a part thereof, wherein the electrical current source is adapted to supply oscillating current to each conduit in such manner that the supply is phase shifted sequentially between adjacent members of the array so as to complete at least a 360° cycle along the said length. It will be seen that to maintain unidirectionality of domain wall propagation the phase shift between adjacent contact pairs must be less than 180°, and that therefore at least three contacts will be required to complete a 360° cycle.

A cycle may comprise more than three contacts as desired. A plurality of cycles may be completed along the said length of an array. Where a plurality of cycles are completed along the said length the directionality of the phase shift progressively along the sequence of the array must be, and the pattern of the phase shift progressively along the sequence of the array conveniently is, repeated with successive cycles.

Thus, the directionality and synchronous clocking that were achieved in the prior art through a rotating magnetic field can also be achieved through spin transfer propulsion.

There is no requirement that the contacts should be equally spaced, as long as they appear topologically in the appropriately phase sifted sequence. Similarly, whilst for convenience it will usually be preferable that the phase spacing between the supply at adjacent contacts is generally constant along the array, this is not a requirement of this embodiment of the invention and for certain applications less regular arrangements might be preferred.

Generally, the oscillating current supply to each contact in the sequence will for convenience have the same amplitude, frequency and waveform, differing only in phase. For certain applications two or more supplies of varying amplitude and/or frequency and/or waveform might be considered subject to the proviso that for unidirectionality the phase shift progressively along the sequence of the array must be in a single direction. The electrical current source may be adapted to provide the required plurality of phase shifted supplies in any known manner.

Conveniently, the foregoing sequentially phase shifted arrangement is achieved in that the driving system comprising a serial array of driving contacts as above described, which contacts comprise a plurality of distinct groups connected in interdigited fashion, each group comprising one or more contacts with a common electrical supply (meaning either a single supply means or a plurality of identical synchronised supply means or a combination thereof), the respective electrical supplies being separately phased. The separate phasing is such that the supply is phase shifted sequentially between adjacent members of the array so as to complete at least one 360° cycle per group pattern repeat.

For example the electrical current source is adapted to supply three separately phased supplied to three distinct interdigited contact groups, preferably such that each supply is generally around ±120° out of phase with the other two.

The continuous track preferably has a width of less than 1 μm, more preferably less than 200 nm, more preferably less than 150 nm and most preferably less than 100 nm. The track width may be constant, or may be varied abruptly or gradually, for example to produce or to mitigate a discontinuity in propagation energy within the conduit to create a magnetic logic element in the manner described in WO 02/41492.

The through thickness of the track is preferably less than 50 nm, more preferably between 5 and 20 nm. Beneath 5 nm, material inconsistencies and production difficulties are likely to be greater. At higher thicknesses power demands will rise. Again, the thickness may be constant throughout the length of the track in any given magnetic logic element or device, or may be varied abruptly or gradually to introduce or mitigate a discontinuity in propagation energy along the track.

The magnetic elements are preferably formed from a soft magnetic material such as Permalloy (Ni80Fe20) or CoFe.

The magnetic material of the conduit may be formed on a substrate. The substrate is either an electrical insulator, or has an insulating barrier layer between the bulk material of the substrate and the conduit. For example a silicon substrate may be used, with a silicon dioxide barrier layer disposed thereupon.

In a further aspect of the invention, a magnetic logic element for a logic device comprises at least one conduit capable of sustaining and propagating a domain wall and provided with a driving system comprising a serial array of driving contacts as above described along the length of the conduit or at least a part thereof, wherein the conduit is further adapted by the provision of nodes and/or directional changes as a result of which logical functions may be processed.

References herein to an element of a logic device or to a logic device or to an element of a logic circuit, are intended to be read as extending to all circuit elements or devices which are known in the art as necessary to make up an effective logic-based system, in particular devices or circuit elements selected from the group comprising interconnects including straight interconnects, comers, branched interconnects and junctions, and logic gates such as AND, OR and NOT gates. Logic circuits manufactured therefrom include a plurality of elements selected from some or all of the foregoing in a suitable arrangement in the usual manner.

Elements will be for example of the architecture described in International Patent Application WO 02/41492. To produce effective interconnects and gates, deviation from strict linearity will be necessary through the provision of nodes, junctions and direction changes in the conduit, which will tend to produce less effective coupling along the track and increase the energy required to propagate a domain wall. The resultant discontinuity in domain wall propagation energy is utilised in accordance with the present invention in logic interconnects and gates and the like.

In accordance with a further aspect of the invention, a method of propagating a magnetic domain wall through a ferromagnetic conduit, for example in a logic system such as that described in the above reference, comprises applying an oscillating electrical current along the conduit between at least two points thereon. In particular, the method comprises applying an electrical current along the conduit at a plurality of points disposed serially therealong for at least part of the length thereof.

In a preferred embodiment the method comprises applying an oscillating electrical current along the conduit at a plurality of points disposed serially therealong wherein the electrical current supply is phase shifted sequentially between adjacent members of the array so as to complete at least a 360° cycle along the said length.

Most preferably, the method comprises applying an oscillating electrical current along the conduit at a plurality of points disposed serially therealong such that electrical current is supplied to contacts comprised as a plurality of distinct groups connected in interdigited fashion, each contact in a group supplied with an identical electrical supply, and the respective electrical supplies being separately phased such that the supply is phase shifted sequentially between adjacent members of the array so as to complete at least one 360° cycle per group pattern repeat. For example three separate voltages are applied to three distinct interdigited contact groups, preferably such that each voltage is around ±120° out of phase with the other two.

According to a further aspect of the invention, a magnetic logic interconnect for a magnetic logic circuit comprises at least one element as above described incorporating the driving system or method above described to propagate a domain wall therein. According to a further aspect of the invention, a magnetic logic gate for a magnetic logic circuit comprises at least one element as above described incorporating the driving system or method above described to propagate a domain wall therein. According to a further aspect of the invention, a magnetic logic circuit comprises a plurality of suitably designed magnetic logic interconnects and magnetic logic gates as above described incorporating the driving system or method above described to propagate a domain wall therein. In such a circuit, magnetic logic elements in accordance with the first aspect of the invention may be arranged to provide OR gates, AND gates, NOT gates, any suitable combination thereof, or any other known logic gates, together with suitable interconnects.

The device or system may further comprise suitable electrical input and/or outputs to enable the magnetic logic device to be used in a larger circuit.

An example of the operation of a the driving system of the invention, and of example magnetic logic devices in accordance with the principles of the invention will now be described referring to the accompanying drawings by way of such illustration, in which:

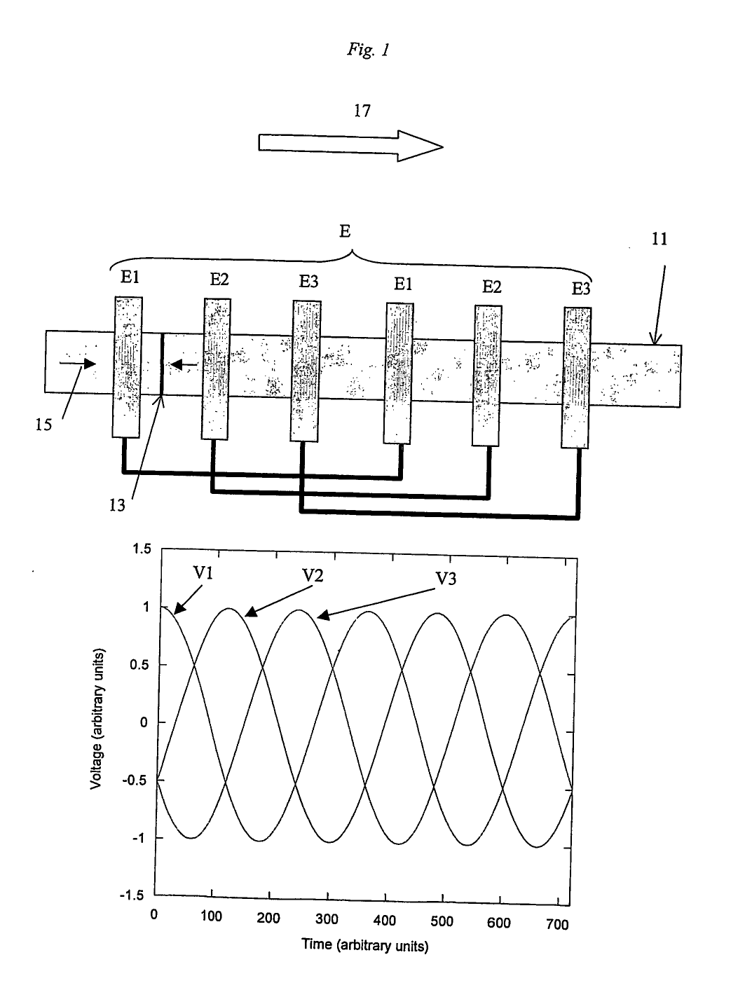

FIG. 1 shows an example of the propagating system of the present invention;

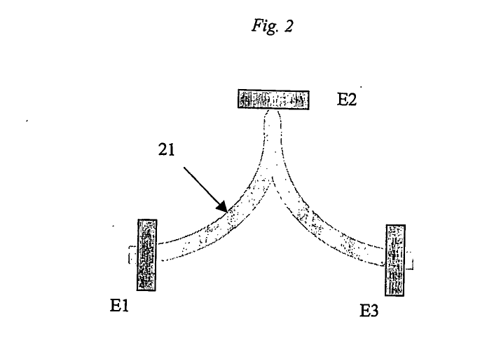

FIG. 2 shows the principles of FIG. 1 applied to a magnetic NOT gate;

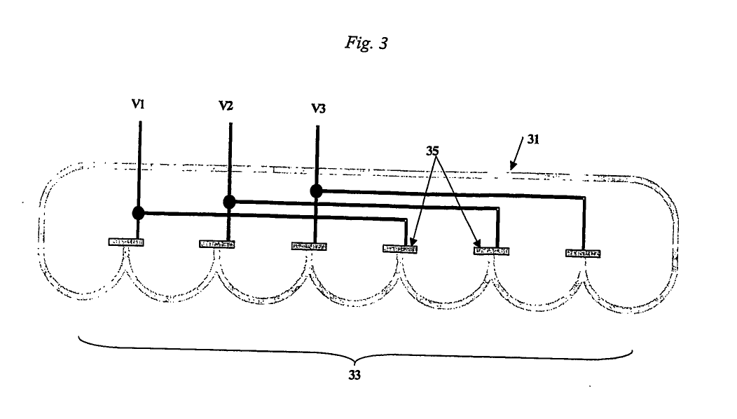

FIGS. 3 to 6 show similar principles applied to other logic elements;

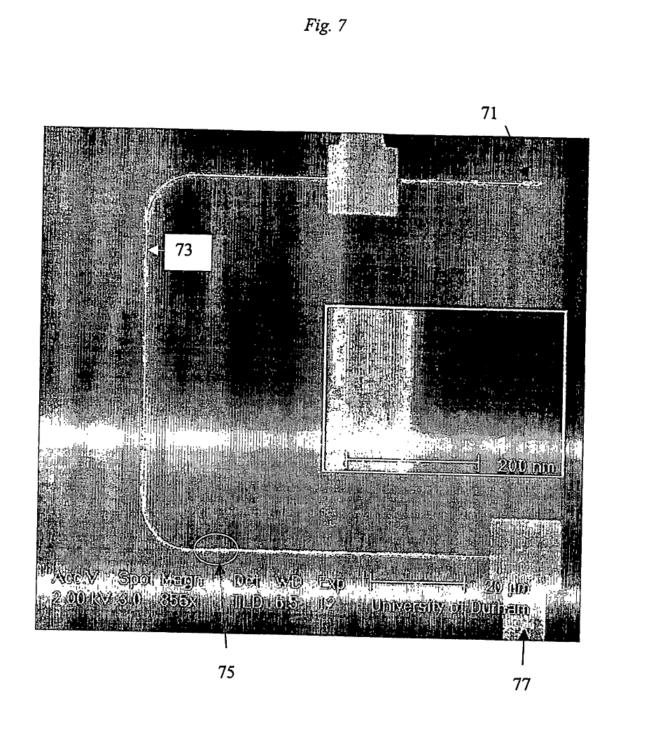

FIG. 7 illustrates an example testing the principles of the invention.

FIG. 1 shows an example of one particular case of the preferred condition wherein three separate voltages are applied to the three distinct contact groups, such that each voltage is ±120° out of phase with the other two, using sinusoidal waveforms.

The figure provides a schematic illustration of a typical sub-micron track of ferromagnetic material (domain wall conduit). A propagating domain wall (13) is shown within the track, with magnetisation direction at either side thereof being indicated by the arrows (15). Electrical connections (E) are made to the domain wall conduit, connected in three different groups (E1, E2, E3). The three different groups have three different applied voltages (V1, V2, V3) with the ±120° out of phase sinusoidal waveforms illustrated in the lower part of the figure.

At the beginning of the first cycle, the net flow of electron current is into contact El (it is the most positive), and so domain walls are propelled towards the nearest contact of type El. During the second one-third of a cycle, the net flow of electron current is into contact E2, and so domain walls are propelled as far as the nearest contact of type E2. During the final one-third of the cycle, the net flow of electron current is into contact E3, and so domain walls are propelled as far as the nearest contact of type E3. The domain wall is thus propelled laterally along the conduit in general direction of the arrow (17).

One sees that as long as the contacts are always ordered in the sequence 1-2-3-1-etc, the wall is steadily propelled from left to right. A minimum of three different electrical phases is required for unidirectional motion. More phases may be used if desired. There is no requirement that the contacts should be equally spaced, as long as they appear topologically in the sequence 1-2-3-1-etc. Thus, the synchronous clocking that was achieved through a rotating magnetic field can also be achieved through spin transfer propulsion.

Synchronous propulsion using 3-phase (or greater) electrical currents will be essential for logic circuits that involve feedback of a Boolean calculation into an earlier part of the logic function. In this case, it is not possible to define a beginning and an end for the information pathway, and so a single electrical current could not carry domain walls all the way through the function. Examples of such circuits include synchronous counters and other finite-state machines [e.g. as described by B. Holdsworth, Digital Logic Design, Chapter 8, Butterworths].

One further case where synchronous clocking is essential is for the NOT gate described in International Patent Application WO 02/41492 and United Kingdom Patent Application 0220907.0. According to these earlier disclosures, a nanomagnetic domain wall NOT gate function can be achieved by twisting the domain wall conduit into the shape of a cusp, or a topological equivalent of it. FIG. 2 shows such a logic element, in which the main wall conduit has been shaped into a cusp (21) to perform NOT function.

The figure illustrates how the three electrical contacts should be made in order to propel a domain wall through such a NOT gate using only spin transfer current, according to this invention. During the first one-third of a cycle, the electron current passes from point E1 to E2, and so the domain wall is propelled from the input into the central vertical arm. During the second one-third of a cycle, the electron current is from point E2 to E3, and so the domain wall is propelled out of the gate. The inversion function is thus complete within the first two-thirds of a cycle.

FIG. 3 shows a 6-bit serial data storage ring in which the domain wall conduit (31) is formed into six concatenated NOT-gates (33), where the electrical connections (35) still appear topologically in the order 1-2-3-1-, but are simpler than those shown in FIG. 2.

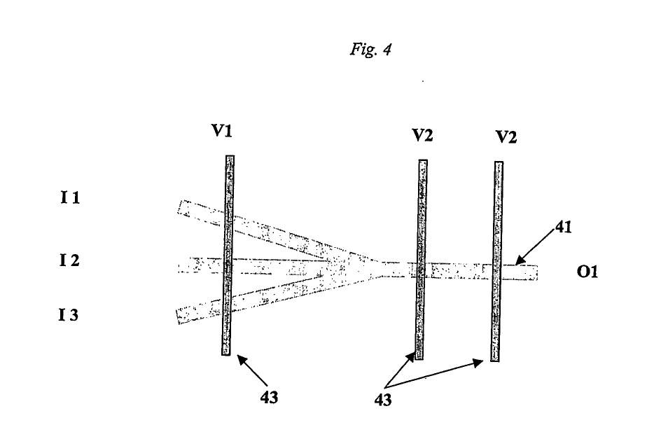

FIG. 4 shows a domain wall conduit (41) configured as a three magnetic input (I1, I2, I3) single magnetic output (O1) MAJORITY gate (see Snider et al. J. Appl. Phys. 85, 4283 (1999) for definition of MAJORITY function) with three electrical connections (43), again with the three applied group voltages (V1, V2, V3).

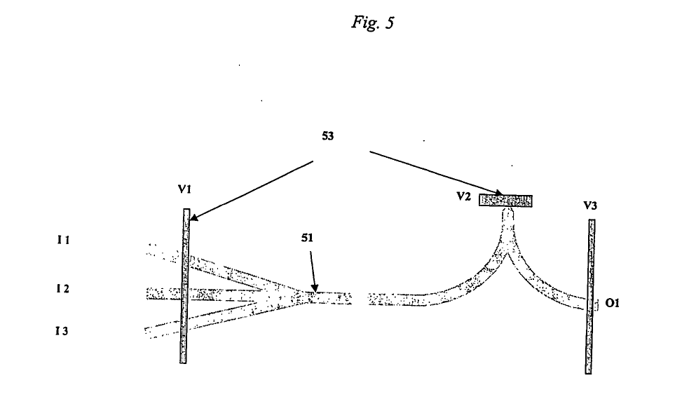

FIG. 5 shows a domain wall conduit (51) configured as a 3-input MAJORITY gate connected to a NOT gate, with three electrical connections (53), as before with the three applied group voltages (V1, V2, V3).

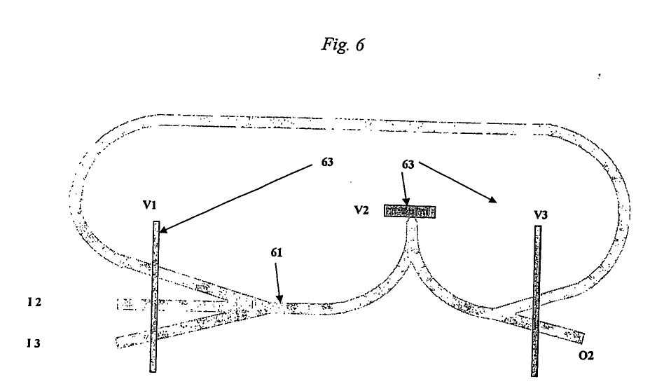

FIG. 6 shows a domain wall conduit (61) configured as a 3-input MAJORITY gate connected to a NOT gate, the output of which is then split into 2 parts: one part (O2) is the output from the function and the other part feeds back into the MAJORITY gate. Three electrical connections are shown (63), with applied voltages (V1, V2, V3).

In order to prove that it is possible to move a domain wall through spin transfer, we have fabricated a 100 nm wide, 5 nm thick domain wall conduit from Permalloy (Ni₈₀Fe₂₀) using electron beam lithography. FIG. 7 shows the sample. The domain wall conduit (73) was in the shape of the letter ‘C’, and a large Permalloy domain wall injector pad (71) was connected at one end of the wire, in order to inject a domain wall. A further electrical connection (77) was made at the other end of the domain wall conduit (73).

The focused laser spot of a magnetooptical magnetometer was placed after the second corner of the conduit at position 75 in order to monitor the magnetic switching of the conduit at the point. A horizontal magnetic field pulse was applied in order to inject the domain wall from the pad and to propagate it as far as the first comer. The magnetometer did not register any change, proving that the domain wall did not propagate completely around the loop. A current of 350 μA was then passed through the wire. As soon as the current was switched on, the magnetometer was found to record a switch, showing that the current had pushed the domain wall all the way from the first corner to the end of the track. This proves the ability of spin transfer to propel a domain wall along a magnetic domain wall conduit.

The invention has been described in particular with reference to logical architectures suggested in International Patent Application WO 02/41492. The invention confers particular advantages over magnetic field drivers for such architecture, but it will be understood that the invention is applicable to any architecture where a logical or other function is obtained by propagating a magnetic domain wall laterally along a ferromagnetic conduit.

1. A driving system to effect propagation of a magnetic domain wall through a ferromagnetic conduit comprises at least two electrical contacts adapted to make electrical connection with at least two spaced points on a ferromagnetic conduit, and an electrical current source to supply oscillating current thereto, and thus in use with the contacts in place to pass an oscillating electrical current through the conduit.

2. A driving system in accordance with claim 1 wherein the electrical current source is adapted to supply oscillating current of up to 100 mA.

3. A driving system in accordance with claim 1 wherein the electrical current source is adapted to supply oscillating current at a frequency of oscillation between 1 kHz and 1 GHz.

4. A ferromagnetic conduit for a magnetic logic system comprising an elongate ferromagnetic element formed as a continuous track of magnetic material capable of sustaining and propagating a domain wall, and a driving system comprising a serial array of electrical contacts spaced along the length of the conduit or a part thereof.

5. A conduit in accordance with claim 4 wherein the contacts in the serial array are evenly spaced.

6. A conduit in accordance with claim 4 wherein the electrical contacts are disposed on the conduit so as to supply an electric current to flow generally in a longitudinal direction along the conduit.

7. A conduit in accordance with claim 4 wherein each electrical contact comprises a contact member extending transversely across the track or a part thereof.

8. A conduit in accordance with claim 4 wherein an electrical current source is adapted to supply oscillating current to each contact in the array in such manner that the supply is phase shifted sequentially between adjacent members of the array so as to complete at least a 360° cycle along the said length.

9. A conduit in accordance with claim 8 wherein the oscillating current supply to each contact in the sequence has the same amplitude, frequency and waveform, differing only in phase.

10. A conduit in accordance with claim 8 wherein the contacts in the serial array comprise a plurality of distinct groups connected in interdigited fashion, each group comprising one or more contacts with a common electrical supply, the respective electrical supplies being separately phased such that the supply is phase shifted sequentially between adjacent members of the array so as to complete at least one 360° cycle per group pattern repeat.

11. A conduit in accordance with claim 10 wherein the electrical current source is adapted to supply three separate phased supplies to three distinct interdigited contact groups.

12. A conduit in accordance with claim 11 wherein each supply is generally around ±120° out of phase with the other two.

13. A conduit in accordance with claim 4 wherein the continuous track has a width of less than 1 μm.

14. A conduit in accordance with claim 4 wherein the through thickness of the track is less than 50 nm.

15. A conduit in accordance with claim 4 wherein the magnetic elements are preferably formed from a soft magnetic material such as Permalloy (Ni80Fe20) or CoFe.

16. A magnetic logic element for a logic device comprising at least one conduit and driving system in accordance with claim 4, wherein the conduit is further adapted by the provision of nodes and/or directional changes as a result of which logical functions may be processed.

17. A method of propagating a magnetic domain wall through a ferromagnetic conduit comprising the step of applying an oscillating electrical current along the conduit between at least two points thereon.

18. The method of claim 17 comprising applying an electrical current along the conduit at a plurality of points disposed serially therealong for at least part of the length thereof.

19. The method of claim 18 wherein the electrical current supply is phase shifted sequentially between adjacent members of the array so as to complete at least a 360° cycle along the said length.

20. The method of claim 19 wherein an oscillating electrical current is supplied along the conduit at a plurality of points disposed serially therealong such that electrical current is supplied to contacts comprised as a plurality of distinct groups connected in interdigited fashion, each contact in a group supplied with an identical electrical supply, and the respective electrical supplies being separately phased such that the supply is phase shifted sequentially between adjacent members of the array so as to complete at least one 360° cycle per group pattern repeat.

21. The method of claim 20 wherein three separate voltages are applied to three distinct interdigited contact groups such that each voltage is around ±120° out of phase with the other two.
